(19) United States
(12) Patent Application Publication
(10) Pub. No.: US 2010/0034622 A1
(43) Pub. Date: Feb. 11, 2010

(54) SUBSTRATE TRANSFER APPARATUS

(76) Inventors: Katsushi Kishimoto, Osaka (JP); Yusuke Fukuoka, Osaka (JP); Hiroyuki Tadokoro, Osaka (JP); Yusuke Ozaki, Osaka (JP)

Correspondence Address: NIXON & VANDERHYE, PC, 901 NORTH GLEBE ROAD, 11TH FLOOR, ARLINGTON, VA, 22203, US

(21) Appl. No.: 12/535,230

(22) Filed: Aug. 4, 2009

(30) Foreign Application Priority Data
Aug. 5, 2008 (JP) 2008-201876

(51) Int. Cl. H01L 21/673

(52) U.S. Cl. 414/222.01

(57) ABSTRACT

A substrate transfer apparatus comprising: a plurality of floating-transfer guide plates adjacent to each other with a space therebetween, each of the guide plates having a substrate-placing surface on which a substrate is to be placed, and a plurality of floating-gas ejecting holes for floating the substrate with use of a gas; a gas supplying source for supplying the floating gas to the respective guide plates; and an arm for transferring the floated substrate from the guide plate, from which the substrate is to be transferred, to the adjacent guide plate to which the substrate is to be transferred, wherein the substrate-placing surface of the guide plate to which the substrate is to be transferred is situated lower than the substrate-placing surface of the guide plate from which the substrate is to be transferred.

### CROSS-REFERENCE TO RELATED APPLICATIONS

This application is related to Japanese application No. 2008-201876 filed on Aug. 5, 2008, whose priority is claimed under 35 USC §119, the disclosure of which is incorporated by reference in its entirety.

### BACKGROUND OF THE INVENTION

1. Field of the Invention

The present invention relates to a substrate transfer apparatus, and more particularly to a substrate transfer apparatus that transfers a substrate, which is a plate-like object to be processed, whose surface is to be subjected to a vacuum process such as a plasma process.

2. Description of the Related Art

A conventional vacuum processing apparatus used for forming or etching a film such as a semiconductor film, insulating film or metal film is generally provided with a load-lock chamber and a vacuum processing chamber. The load-lock chamber is evacuated after a substrate is carried therein, and the substrate is then preheated by a heater. The substrate preheated in the load-lock chamber is carried in the vacuum processing chamber where the substrate is subjected to a film-forming process or etching process.

In such a vacuum processing apparatus described above, it is necessary that heated substrates are continuously carried in the vacuum processing chamber and are continuously processed therein so as to increase production efficiency. Therefore, the vacuum processing apparatus is further provided with an unload-lock chamber, to which the substrates are transferred from the vacuum processing chamber.

A vacuum processing apparatus disclosed in Japanese Unexamined Patent Publication No. 2001-239144 and WO 2005/74020 each has been also known as such a type of the vacuum processing apparatus described above.

In a specific vacuum processing apparatus among the vacuum processing apparatuses of this type, a substrate preheated by a heater is placed on a substrate-placing surface of a guide plate from which the substrate is to be transferred, and is then transferred, while floating in a substantially horizontal state, to a substrate-placing surface of a guide plate to which the substrate is to be transferred. During the floating transfer, an end portion or a side edge portion of the heated substrate might be curved downwardly due to its own weight or decreasing temperature. As a result, troubles related to the transfer of the substrate could arise, such that a part of the substrate, which is curved downwardly, could be caught by the guide plate to which the substrate is to be transferred, or could rub the substrate-placing surface of this guide plate.

### SUMMARY OF THE INVENTION

The present invention is accomplished in view of the foregoing circumstances, and aims to provide a substrate transfer apparatus that can prevent the troubles related to the substrate transfer, such that the part of the substrate is curved downwardly during the transfer and caught by the guide plate to which the substrate is to be transferred, or the part of the substrate rubs the substrate-placing surface of the guide plate.

The present invention provides a substrate transfer apparatus comprising:

a plurality of floating-transfer guide plates adjacent to each other with a space therebetween, each of the guide plates having a substrate-placing surface on which a substrate is to be placed, and a plurality of floating-gas ejecting holes for floating the substrate with use of a gas;

a gas supplying source for supplying the floating gas to the respective guide plates; and

an arm for transferring the floated substrate from the guide plate, from which the substrate is to be transferred, to the adjacent guide plate to which the substrate is to be transferred, wherein

the substrate-placing surface of the guide plate to which the substrate is to be transferred is situated lower than the substrate-placing surface of the guide plate from which the substrate is to be transferred.

### BRIEF DESCRIPTION OF THE DRAWINGS

FIG. 1 is a partially cutout perspective view showing a substrate transfer apparatus, which is incorporated in a plasma processing apparatus, according to a first embodiment of the present invention;

FIG. 2 is a perspective view of a second guide plate and a third guide plate constituting the substrate transfer apparatus shown in FIG. 1;

FIG. 3 is an explanatory view for explaining one stage of the transfer in the substrate transfer apparatus shown in FIG. 1;

FIG. 4 is an explanatory view for explaining another stage of the transfer in the substrate transfer apparatus shown in FIG. 1;

FIG. 5 is an explanatory view for explaining still another stage of the transfer in the substrate transfer apparatus shown in FIG. 1;

FIG. 6 is an explanatory view for explaining yet another stage of the transfer in the substrate transfer apparatus shown in FIG. 1;

FIG. 7 is an explanatory view for explaining yet another stage of the transfer in the substrate transfer apparatus shown in FIG. 1;

FIG. 8 is a perspective view showing a first modification of the second guide plate and the third guide plate shown in FIG. 2;

FIG. 9 is a perspective view showing a second modification of the second guide plate and the third guide plate shown in FIG. 2;

FIG. 10 is a perspective view showing a third modification of the second guide plate and the third guide plate shown in FIG. 2;

FIG. 11 is a perspective view showing a fourth modification of the second guide plate and the third guide plate shown in FIG. 2;

FIG. 12 is a partially cutout perspective view of a substrate transfer apparatus, which is incorporated in a plasma processing apparatus, according to a second embodiment of the present invention; and

FIG. 13 is a plan view of a tray for mounting a substrate, which is one component in the substrate transfer apparatus shown in FIG. 12.

### DETAILED DESCRIPTION OF THE PREFERRED EMBODIMENTS

A “floating gas” in the specification and the claims of the present invention means a gas that floats a substrate.

The plurality of floating-transfer guide plates in the substrate transfer apparatus are arranged so as to be spaced from each other. Such a guide plate does not require a particular structure as long as it functions as a guide when the floated substrate is transferred by means of the arm, and has the substrate-placing surface on which the substrate is placed, the substrate being a plate-like object to be transferred and processed, and the plurality of floating-gas ejecting holes. In this case, a shape and material of the guide plate are not particularly limited.

Each of the guide plates is made of, for example, a rectangular plate member and has a floating-gas supplying tube connected to an external gas supplying source. The guide plates are respectively arranged in a straight line along a transfer direction of the substrate in a plurality of processing chambers adjacent to each other via a gate valve. Each of the guide plates is supplied with a gas supplied from the gas supplying source. The gas is not particularly limited as long as it does not cause damage to the guide plate, the substrate, and the like. Preferable examples of the floating gas include nitrogen gas, helium gas, argon gas, etc.

The plurality of (e.g., 100 to 200) floating-gas ejecting holes (each having, for example, a hole diameter ranging from 0.5 mm to 5.0 mm) on the respective guide plates can be constituted of, for example, a plurality of ejecting hole groups (e.g., 5 to 10 groups) which are independent from each other. The ejecting hole groups are transversely placed with respect to the transfer direction and placed at predetermined intervals in the transfer direction.

The arm is to transfer the substrate, which floats by means of the floating gas, from the substrate-placing surface of the guide plate on which the substrate has been placed to the substrate-placing surface of the adjacent guide plate.

The arm is constituted of, for example, a base portion, a guide portion, and an arm portion. The base portion of such an arm can horizontally reciprocate along a rail paralleling the transfer direction. The guide portion is provided to the base portion, and is configured to horizontally reciprocate in a direction orthogonal to the transfer direction. The arm portion is provided to the guide portion, is horizontally placed in parallel with the transfer direction, and is configured to be placed at a side of the substrate placed on the guide plate. The substrate may be transferred by means of a pair of the arms. The arm portion is provided with an inward projecting end as a free end. The inward projecting end contacts and engages, from an outer side to an inner side of the arms, with a part of the substrate, and disengages therefrom from the inner side to the outer side, due to the horizontal reciprocating movement of the guide portion.

To drive the arm, for example, a mechanism is used, constituted of a pair of pulleys spaced from each other in the transfer direction, a wire looped around the pulleys, and a motor connected to one of the pulleys.

In the substrate transfer apparatus according to the present invention, the substrate-placing surface of the guide plate to which the substrate is to be transferred is situated lower than the substrate-placing surface of the guide plate from which the substrate is to be transferred. However, it is preferable that at least one of the guide plate from which the substrate is to be transferred and the guide plate to which the substrate is to be transferred is configured to change its height by means of, for example, an elevation mechanism.

A height difference between the substrate-placing surface of the guide plate from which the substrate is to be transferred and the substrate-placing surface of the guide plate to which the substrate is to be transferred can appropriately set in consideration of a size, weight, and material of the substrate, or a condition of the preheating process of the substrate. The height difference is set, for example, to be about 1 to 10 mm.

It is preferable that the substrate transfer apparatus according to the present invention is configured to be provided with a leading portion placed at an end portion of the guide plate, to which the substrate is to be transferred, opposite to the guide plate from which the substrate is to be transferred. The leading portion is to lead the substrate to be transferred from the substrate-placing surface of the guide plate from which the substrate is to be transferred to the substrate-placing surface of the guide plate to which the substrate is to be transferred.

The leading portion is configured, for example, to have a surface inclined downwardly from the substrate-placing surface of the guide plate, from which the substrate is to be transferred, to the end portion of the guide plate. The floated substrate can be transferred even if a part of the substrate, placed on the substrate-placing surface of the guide plate from which the substrate is to be transferred, is curved downwardly, since the curved portion of the substrate, which is to be transferred while floating, is brought into contact with the inclined surface and is directed upwardly so as to be led to the substrate-placing surface of the guide plate to which the substrate is to be transferred.

The guide plate provided with the leading portion may be provided, at its end portion, with a particle receiving portion having a concave shape for receiving a particle. A “particle” in the specification and the claims of the present invention means a particle-like minute flake partially exfoliated by friction between the substrate or a substrate-mounting/transferring tray and the guide plate. When the particle receiving portion is provided to the end portion of the guide plate, the particle partially exfoliated by the friction between the substrate or the substrate-mounting/transferring tray and the guide plate can be prevented from falling down below the chamber. Accordingly, the particle receiving portion can prevent the particle from attaching onto a seal portion of the gate valve, and also can reduce maintenance frequency of the seal portion.

The leading portion may be composed of a transfer auxiliary roller. The transfer auxiliary roller is brought into contact with the portion of the substrate that is curved downwardly during the transfers and directs the curved portion upwardly so as to lead the substrate to the substrate-placing surface of the guide plate to which the substrate is to be transferred. The transfer auxiliary roller may be only one roller or may include a plurality of rollers spaced from each other in a direction vertical to the transfer direction.

In the substrate transfer apparatus according to the present invention, it is preferable that at least one of the guide plate from which the substrate is to be transferred and the guide plate to which the substrate is to be transferred is configured to change its height by means of the elevation mechanism. The elevation mechanism is to desirably set a height difference between the substrate-placing surface of the guide plate from which the substrate is to be transferred and the substrate-placing surface of the guide plate to which the substrate is to be transferred.

In some cases, the substrate transfer apparatus according to the present invention may be configured to be further provided with a tray on which the substrate is mounted, the tray being floated by the floating gas, wherein the tray has a taper portion whose thickness gradually decreases in the transfer direction, the taper portion being placed at an end portion of the tray opposite to the guide plate to which the substrate is to be transferred. The taper portion of the tray is brought into contact with the portion of the substrate that is curved downwardly during the transfer, and smoothly leads the substrate to the substrate-placing surface of the guide plate to which the substrate is to be transferred.

The tray on which the substrate is mounted is not particularly limited in shape and material as tong as it can endure temperatures and pressures in various processes while the substrate is mounted thereon. However, it is preferable that the tray is light in weight from the viewpoint of being floated by the floating gas. For example, the tray may be made of a thin plate (having a thickness of 0.5 mm to 2.0 mm, for example) of stainless steel or an aluminum alloy.

The substrate transfer apparatus according to the present invention is provided with the plurality of floating-transfer guide plates, the gas supplying source, and the transfer arm in the specific configuration described above, wherein the substrate-placing surface of the guide plate to which the substrate is to be transferred is situated lower than the substrate-placing surface of the guide plate from which the substrate is to be transferred.

Consequently, according to the substrate transfer apparatus described above, even when a part Of the substrate is curved downwardly on the substrate-placing surface of the guide plate from which the substrate is transferred, the substrate can be transferred onto the substrate-placing surface of the guide plate to which the substrate is to be transferred without causing the conventional troubles related to the transfer of the substrate such that the part of the substrate is caught by the guide plate to which the substrate is to be transferred or rubs the substrate-placing surface of the guide plate. Therefore, the possibility of the troubles related to the transfer of the substrate can be prevented.

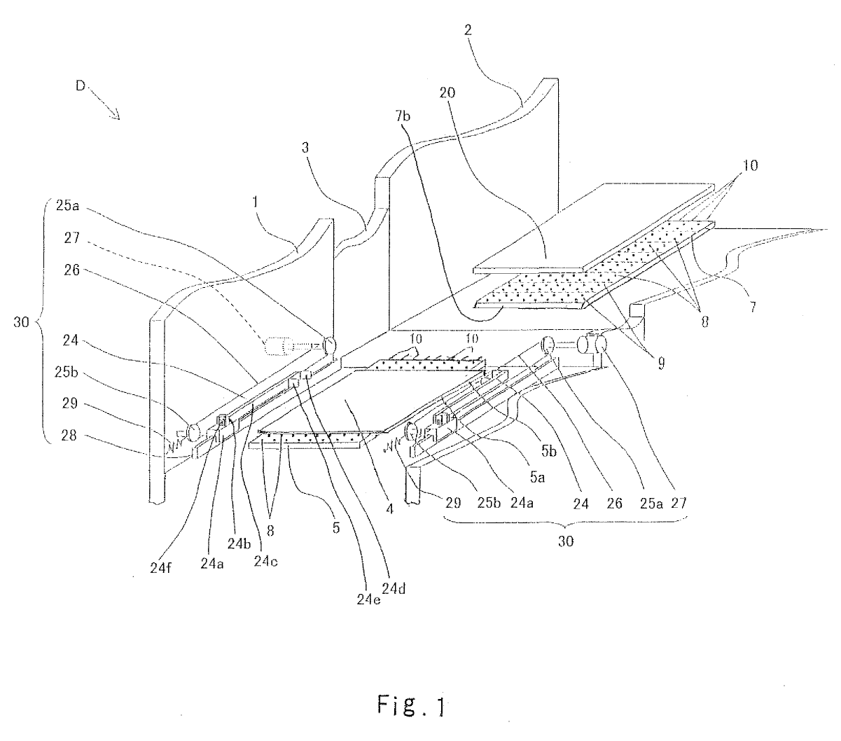

The present invention will be described in the following two embodiments with reference to FIGS. 1 to 13 attached herewith. It is to be noted that the present invention is not limited to these embodiments.

### First Embodiment

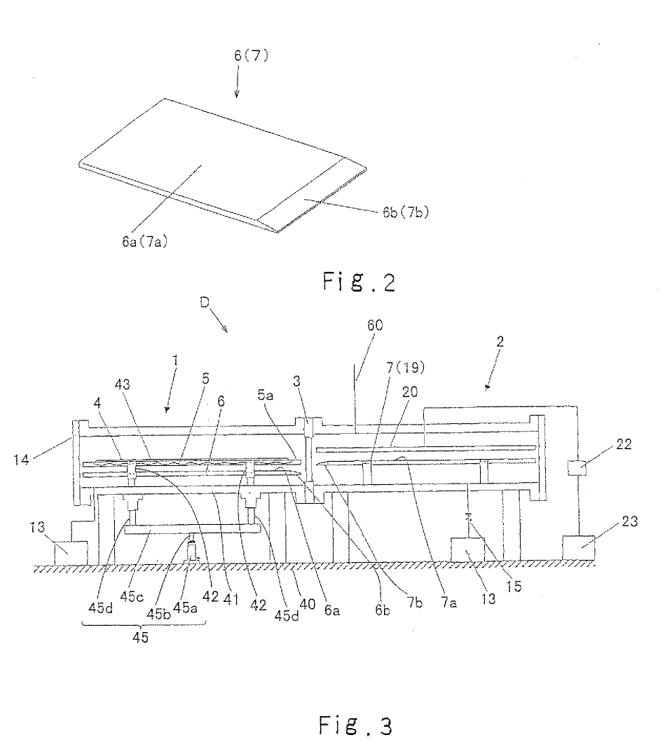

FIG. 1 is a partially cutout perspective view of a substrate transfer apparatus, which is incorporated in a plasma processing apparatus, according to a first embodiment of the present invention. FIG. 2 is a perspective view of a second guide plate and a third guide plate constituting the substrate transfer apparatus shown in FIG. 1. FIGS. 3 to 7 are explanatory views for explaining each stage of the transfer in the substrate transfer apparatus according to the first embodiment of the present invention.

The substrate transfer apparatus D shown in FIGS. 1 to 3 in the first embodiment of the present invention is incorporated in a plasma processing apparatus. The substrate transfer apparatus D has a first vacuum chamber 1 and a second vacuum chamber 2 that are adjacent to each other horizontally with a space at a position with a predetermined height from an installation surface 40. These two vacuum chambers 1 and 2 are configured such that one casing linearly extending in a longitudinal direction is divided into two by a single separation gate valve 3 that can be opened and closed.

The vacuum chambers 1 and 2 are made of stainless steel, and a mirror finish is provided on an inner surface thereof. The gate valve 3 is configured to be capable of moving up and down. The gate valve 3 allows the adjacent two vacuum chambers 1 and 2 to communicate with each other when it is at the moving-up position, while it allows the adjacent two vacuum chambers 1 and 2 to be separated from each other when it is at the moving-down position.

The first vacuum chamber 1 is specified as an LL/UL chamber for load-locking/unload-locking a plasma processing substrate 6. The second vacuum chamber 2 is specified as a process chamber for performing a desired plasma process to the substrate 6 that is transferred therein.

The LL/UL chamber 1 serving as the first vacuum chamber and the process chamber 2 serving as the second vacuum chamber are provided with first to third guide plates 5, 6, and 7 used for a floating transfer and composed of a rectangular flat plate member. A substrate 4, which is to be transferred as being floated or which is transferred as being floated, is placed onto substrate-placing surfaces 5a, 6a, and 7a which is a top surface of the first to the third guide plates 5, 6, and 7. The first to third guide plates 5, 6, and 7 are also made of stainless steel, and have partially a hollow structure. The respective guide plates 5, 6, and 7 are subjected to a mirror finish on the surface thereof, and have a width (i.e. a length of a short side) of 600 mm, a length (i.e. a length of a long side) of 1000 mm, and a thickness of 30 mm.

The first guide plate 5 and the second guide plate 6 in the LL/UL chamber I are vertically arranged. Specifically, the first guide plate 5 and the second guide plate 6 are fixed and held by holding portions 42 and 42, which are provided upwardly from a bottom wall 41 of the LL/UL chamber 1, so as to be parallel to each other with a predetermined space vertically and horizontally.

The guide plate 5 that is the upper one has incorporated therein a heater 43 for heating the substrate 4. The first guide plate 5 is used for load-locking the substrate 4. The second guide plate 6 that is the lower one is used for taking the substrate that has been subjected to the plasma process. The first guide plate 5 and the second guide plate 6 are configured such that the height of the substrate-placing surfaces 5a and 6a of the guide plates 5 and 6 is changed by an elevation mechanism 45.

The elevation mechanism 45 includes a drive portion 45a provided on the installation surface 40 below the bottom wall 41 of the LL/UL chamber 1, a vertical coupling portion 45b coupled to the drive portion 45a so as to be capable of moving up and down, a horizontal coupling portion 45c, and elevation columns 45d and 45d that are provided upwardly from the end portions of the horizontal coupling portion 45c for connecting the horizontal coupling portion 45c and the holding portions 42 and 42, and that can move up and down through the bottom wall 41.

The drive portion 45a drives the holding portions 42 and 42 so as to allow them to move up and down through the vertical coupling portion 45b, the horizontal coupling portion 45c and columns 45d and 45d with a hydraulic cylinder or motor. With this operation of the elevation mechanism 45, the first guide plate 5 and the second guide plate 6 can move up and down in the LL/UL chamber 1 with the predetermined space between both guide plates 5 and 6 maintained.

As shown in FIG. 3, a gas supplying tube 60 is connected to the substrate transfer apparatus D for supplying a plasma-process reaction gas to the process chamber 2 from an external gas supplying source (not shown).

The LL/UL chamber 1 and the process chamber 2 are connected to external vacuum valves 13, 13. A door 14 for carrying-in/discharging the substrate is provided to the LL/UL chamber 1. The process chamber 2 is connected to the vacuum valve 13 below the chamber 2 via a pressure regulating valve 15 for keeping the interior of the chamber to have a predetermined vacuum.

The third guide plate 7 in the process chamber 2 also serves as a plasma-processing anode electrode 19. A plasma-processing cathode electrode 20 is provided above the anode electrode 19 so as to oppose to the anode electrode 19. The cathode electrode 20 is electrically connected to a high-frequency power supply 23 through a condenser (not shown) and a rectifying circuit 22 at the outside of the process chamber 2.

As shown in FIG. 1, each of the guide plates 5, 6, and 7 (the second guide plate 6 is not shown in FIG. 1) is formed with a plurality of floating-gas ejecting holes 8, . . . 8. Specifically, 128 circular gas ejecting holes in total 8, . . . 8 are formed on a top surface of each of the guide plates 5, 6, and 7, in which 8 holes are formed in one row in a direction in which the short side of a rectangle extends (the direction orthogonal to the transfer direction), and the holes are formed in 16 rows in a direction in which the long side of the rectangle extends (the direction parallel to the transfer direction). The diameter of each pf the gas ejecting holes 8 is 1.0 mm.

These 128 gas ejecting holes 8, . . . 8 arc divided into independent 8 band-like ejecting hole groups 9, . . . 9 including 2 rows having 16 holes. These ejecting hole groups 9, . . . 9 are transversely formed in the transfer direction, which is the direction in which the long side of each of the guide plates 5, 6, and 7 extends, and formed with a predetermined space in the transfer direction.

Each of the guide plates 5, 6, and 7 has 8 inner grooves (not shown) corresponding to 8 band-like ejecting hole groups 9, . . . 9, which are transversely formed in the transfer direction, and formed with a predetermined space in the transfer direction, and 8 floating gas supplying tubes 10, . . . 10 that are connected so as to communicate with these inner grooves and extend along the transfer direction in the guide plates 5, 6, and 7.

As shown in FIG. 1, the substrate transfer apparatus D has transfer function units 30, 30 provided to the LL/UL chamber 1. The transfer function units 30, 30 allow the substrate 4 placed onto the guide plates 5, 6, and 7 to float, and transfer the floated substrate 4 between the LL/UL chamber 1 and the process chamber 2 along the guide plates 5, 6, and 7 with external force.

As shown in FIG. 2, a leading portion 6b for leading the substrate 4 from the substrate-placing surface 7a of the third guide plate 7 to the substrate-placing surface 6a of the second guide plate 6 is formed at the end portion (opposite end portion) of the second guide plate 6 opposite to the third guide plate 7. Further, a leading portion 7b for leading the substrate 4 from the substrate-placing surface 5a of the first guide plate 5 to the substrate-placing surface 7a of the third guide plate 7 is formed at the end portion (opposite end portion) of the third guide plate 7 opposite to the first guide plate 5.

Each of the leading portion 6b at the second guide plate 6 and the leading portion 7b at the third guide plate 7 has an inclined surface that is inclined downwardly from the substrate-placing surface 7a of the third guide plate 7 and the substrate-placing surface 6a of the second guide plate 6 toward the corresponding opposite end portions.

The configuration of the transfer function units 30 and 30 will be described with reference to FIG. 1.

In FIG. 1, each of the transfer function units 30, 30 move the substrate 4 between the LL/UL chamber 1 and the process chamber 2. Each of the transfer function units 30, 30 has a transfer arm 24 arranged along both side edges of the first guide plate 5 in the LL/UL chamber 1, a pair of pulleys (a drive pulley 25a and a driven pulley 25b) arranged in the transfer direction with a space, a wire 26 looped around these pulleys 25a and 25b, and a motor 27 connected to the drive pulley 25a.

A spring 29 that is urged in a direction of taking up the slack of the wire 26 is mounted to the driven pulley 25b. The spring 29 pulls the driven pulley 25b in the direction parallel to the transfer direction, so that the tension of the wire 26 is kept to be constant.

The transfer arm 24 includes a base portion 24a, a guide portion 24b, and an arm portion 24c. A part of the transfer arm 24 is coupled to the wire 26, and placed onto a rail 28 provided horizontally at the LL/UL chamber 1.

Specifically, the base portion 24a is coupled to the wire 26 and mounted to the rail 28, so that the base portion 24a can reciprocate horizontally along the rail 28. The guide portion 24b can reciprocate horizontally in the direction orthogonal to the transfer direction at the base portion 24a. The arm portion 24c is provided horizontally in the direction parallel to the transfer direction at the guide portion 24b, and provided so as to be positioned at the side of the placed substrate 4. The moving distance of the arm portion 24c in the transfer direction is set to be 650 mm.

The arm portion 24c is formed with first and second inward projecting ends 24d and 24e at its free end. The inward projecting ends 24d and 24e are brought into contact with and engaged with both side edges of the substrate 4 or are disengaged therefrom.

More specifically described, a gear 24f is provided at the top surface of the base portion 24a via a vertical rotational axis (not shown). The gear 24f is supported to the base portion 24a so as to be rotatable. When the gear 24f is rotatably engaged with one side face of the guide portion 24b (the side face where a gear groove engaged with the gear 24f is formed), it allows the guide portion 24b to reciprocate in the direction orthogonal to the transfer direction.

Due to the reciprocating movement of the guide portion 24b, the arm portion 24c is apart from the rail 28 or close to the rail 28 with the parallel relationship between the arm portion 24c and the rail 28 maintained. With the movement of the arm portion 24c described above, the inward projecting ends 24d and 24e of the arm portion 24c is brought into contact with and engaged with the side edge of the substrate 4 from the outer side (the side more apart from the side edge of the substrate 4) toward the inner side (the side closer to the side edge of the substrate 4) or disengaged therefrom from the inner side toward the outer side.

The substrate transfer apparatus D further includes a sensor (not shown) for detecting the position of the substrate 4 that is now being transferred, and a control function unit (not shown) for performing a predetermined control.

The control function unit mainly performs the control described below. Specifically, it opens the gate valve 3 so as to allow the adjacent LL/UL chamber 1 and the process chamber 2 to communicate with each other. Further, the control function unit allows the floating gas to be ejected from the gas ejecting holes 8, . . . 8 at the guide plates 5, 6 and 7 in the LL/UL chamber 1 and the process chamber 2. Then, the control function unit causes the floating gas to be sequentially ejected from the ejecting hole groups 9, . . . 9 involved with the floating of the substrate 4 in the LL/UL chamber 1 and the process chamber 2 in order to make the floating transfer control for transferring the substrate 4, which is floated by the ejected floating gas, along the guide plates 5, 6, and 7 by the transfer function units 30, 30. The control function unit also sequentially stops the ejection of the floating gas from the ejecting hole groups 9, . . . 9 that are not involved with the floating of the substrate 4.

The floating transfer operation and the plasma processing operation of the substrate transfer apparatus D will be described below with reference to FIGS. 3 to 7.

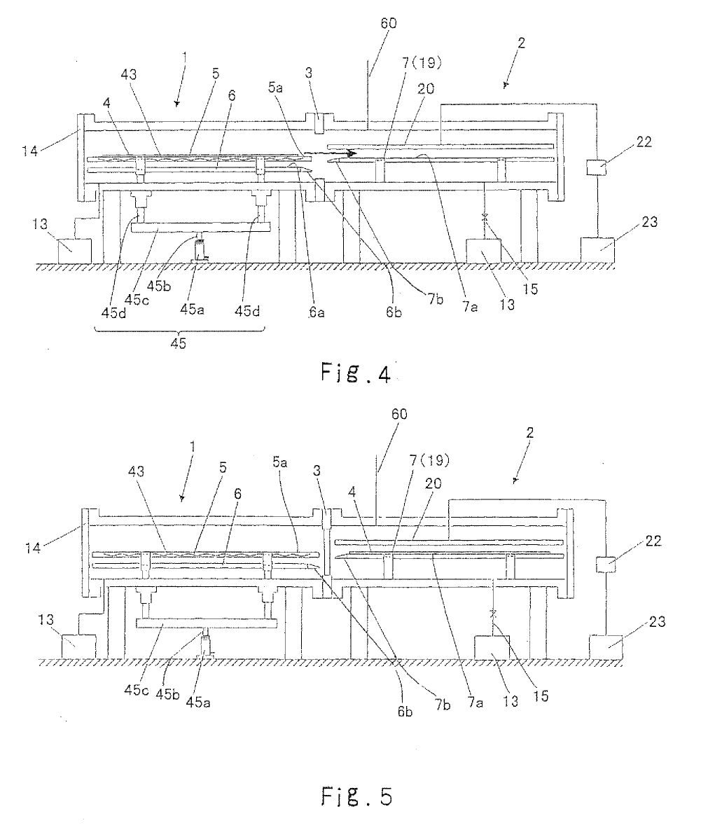

As shown in FIG. 3, the substrate 4 is placed onto the substrate-placing surface 5a of the first guide plate 5 in the LL/UL chamber 1. Thereafter, the vacuum pump 13 is operated to evacuate the LL/UL chamber 1. The substrate 4 is heated by the heater 43 incorporated in the first guide plate 5. When the temperature of the substrate 4 is raised to a desired temperature, the gate valve 3 is opened, so that the LL/UL chamber 1 and the process chamber 2 communicate with each other as shown in FIG. 4.

Then, the substrate 4 placed onto the substrate-placing surface 5a of the first guide plate 5 in the LL/UL chamber 1 is floated as described above to be transferred to the substrate-placing surface 7a of the third plate 7 in the process chamber 2 by the transfer arms 24 and 24 (along an arrow in FIG. 4).

Before the floating transfer described above, the substrate-placing surface 5a of the first guide plate 5 is situated higher than the substrate-placing surface 7a of the third guide plate 7 by about 3 mm by the operation of the elevation mechanism 45 (see FIGS. 3 and 4).

For the floating transfer of the substrate 4 from the substrate-placing surface 5a of the first guide plate 5 to the substrate-placing surface 7a of the third guide plate 7, the substrate-placing surface 5a of the first guide plate 5 is situated higher than the substrate-placing surface 7a of the third guide plate 7 by about 3 mm. Further, the leading portion 7b provided with the inclined surface is formed to the third plate 7.

Accordingly, even if a part of the substrate 4 is curved downwardly on the substrate-placing surface 5a of the first guide plate 5, the curved portion is brought into contact with the inclined surface of the leading portion 7b at the third guide plate 7, whereby the curved portion is directed upwardly. Therefore, the substrate 4 can be smoothly transferred from the higher substrate-placing surface 5a to the lower substrate-placing surface 7a through the leading portion 7b without causing troubles such that a part of the substrate 4 is caught by the third guide plate 7 or rubs the third guide plate 7.

Next, the substrate 4 is transferred to the substrate-placing surface 7a of the third guide plate 7 in the process chamber 2, and then, the gate valve 3 is closed as shown in FIG. 5. Thereafter, the reaction gas is introduced into the process chamber 2 from the gas supplying tube 60, whereby the process chamber 2 is kept to have a predetermined pressure by the pressure regulating valve 15.

Subsequently, power is supplied to the cathode electrode 20 from the power supply 23 through the rectifying circuit 22. With this, plasma is produced between the cathode electrode 20 and the anode electrode 19 (the third guide plate 7), whereby the substrate 4 is subjected to the plasma process. Examples of the plasma process here include a plasma CVD or plasma etching.

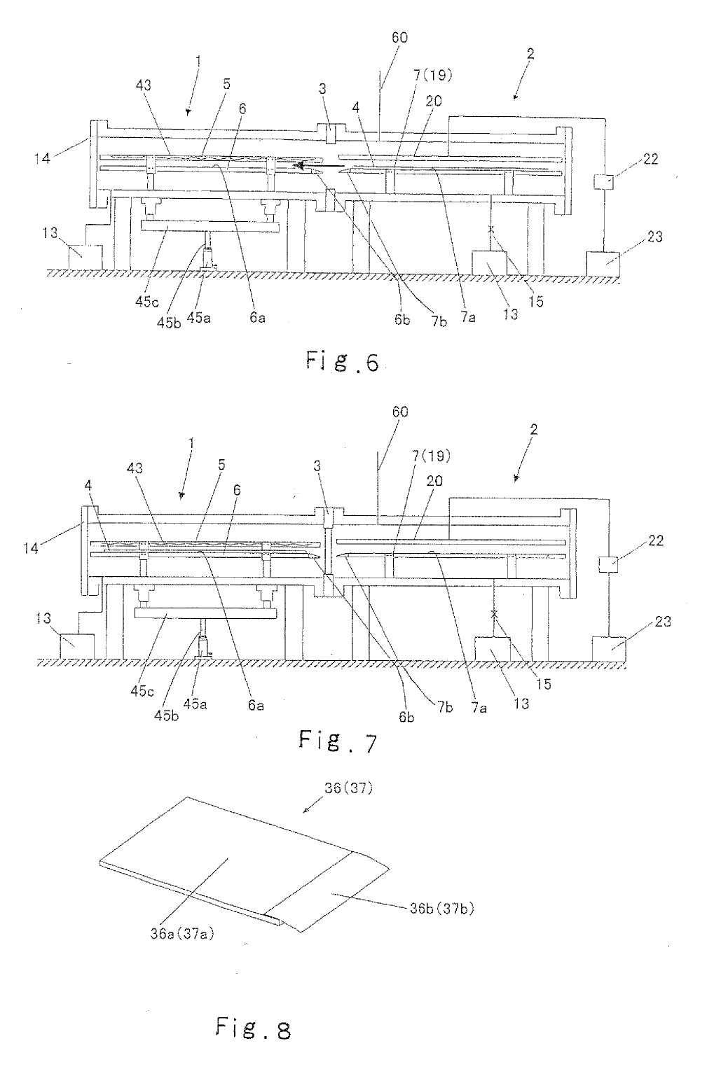

After the plasma process is completed, the gate valve 3 is opened as shown in FIG. 6, whereby the substrate 4 placed onto the substrate placing surface 7a of the third guide plate 7 is transferred, as being floated, to the substrate-placing surface 6a of the second guide plate 6 in the same manner as described above (along an arrow in FIG. 6).

Before the floating transfer, the substrate-placing surface 6a of the second guide plate 6 is situated lower than the substrate-placing surface 7a of the third guide plate 7 by about 3 mm by the operation of the elevation mechanism 45 (see FIG. 6).

For the floating transfer of the substrate 4 from the substrate-placing surface 7a of the third guide plate 7 to the substrate-placing surface 6a of the second guide plate 6, the substrate placing surface 6a of the second guide plate 6 is situated lower than the substrate-placing surface 7a of the third guide plate 7 by about 3 mm. Further, the leading portion 6b provided with the inclined surface is formed to the second plate 6.

Accordingly, even if a part of the substrate 4 is curved downwardly on the substrate-placing surface 7a of the third guide plate 7, the curved portion is brought into contact with the inclined surface of the leading portion 6b at the second guide plate 6, whereby the curved portion is directed upwardly. Therefore, the substrate 4 can be smoothly transferred from the higher substrate-placing surface 7a to the lower substrate-placing surface 6a through the leading portion 6b without causing troubles such that a part of the substrate 4 is caught by the second guide plate 6 or rubs the second guide plate 6.

Next, the substrate 4 is transferred to the substrate-placing surface 6a of the second guide plate 6 in the LL/UL chamber 1, and then, the gate valve 3 is closed as shown in FIG. 7. Thereafter, the LL/UL chamber 1 is leaked, and the door 14 for carrying-in/discharging the substrate is opened, so that the substrate 4 is taken out from the LL/UL chamber 1.

At the time of taking out the substrate 4, the reason why the substrate 4 is returned to the second guide plate 6, not to the first guide plate 5 is as described below. Specifically, the first guide plate 5 has high temperature since it is heated by the incorporated heater 43. Therefore, it takes much time to drop the temperature after the plasma process. Further, the next substrate 4 has to be prepared onto the substrate-placing surface 5a of the first guide plate 5 during the plasma process.

According to the substrate transfer apparatus D described above, even when a part of the substrate 4 is curved downwardly on the substrate-placing surface (5a or 7a) of the guide plate from which the substrate 4 is to be transferred (the first guide plate 5 or the third guide plate 7), the curved portion is brought into contact with the inclined surface of the leading portion (7b or 6b) at the guide plate to which the substrate 4 is to be transferred (the third guide plate 7 or the second guide plate 6), whereby the curved portion is directed upwardly.

Therefore, the substrate 4 can be smoothly transferred from the higher substrate-placing surface (5a or 7a) to the lower substrate-placing surface (7a or 6a) through the leading portion (7b or 6b) without causing troubles such that a part of the substrate 4 is caught by the guide plate to which the substrate 4 is to be transferred (the third guide plate 7 or the second guide plate 6) or rubs the guide plate. Consequently, the substrate transfer apparatus D can prevent the possibility of the conventional troubles related to the transfer of the substrate.

### Modification of First Embodiment

FIGS. 8 to 11 show another second guide plate and third guide plate (first to fourth modifications) provided instead of the second guide plate and the third guide plate constituting the substrate transfer apparatus D in the first embodiment.

### [First Modification]

A second guide plate 36 according to a first modification in the first embodiment shown in FIG. 8 includes a main body portion having a substrate-placing surface 36a, and a guide plate 36b, serving as the guide portion, formed at the end portion (opposite end portion) of the main body portion opposite to a third guide plate 37 for guiding the substrate 4 from a substrate-placing surface 37a of the third guide plate 37 to the substrate-placing surface 36a of the second guide plate 36. The guide plate 36b is provided at the opposite end portion of the substrate-placing surface 36a at the main body portion, and has a convex curved face that is gently inclined downwardly from the substrate-placing surface 36a.

Similarly, the third guide plate 37 according to the first modification includes a main body portion having the substrate-placing surface 37a, and a guide plate 37b, serving as the leading portion, formed at the end portion (opposite end portion) of the main body portion opposite to the first guide plate 5 for leading the substrate 4 from the substrate-placing surface 5a of the first guide plate 5 to the substrate placing-surface 37a of the third guide plate 37. The guide plate 37b is provided at the opposite end portion of the substrate-placing surface 37a at the main body portion, and has a convex curved face that is gently inclined downwardly from the substrate-placing surface 37a.

The other configurations of the substrate transfer apparatus in the first modification are substantially the same as those of the substrate transfer apparatus D in the first embodiment.

### [Second Modification]

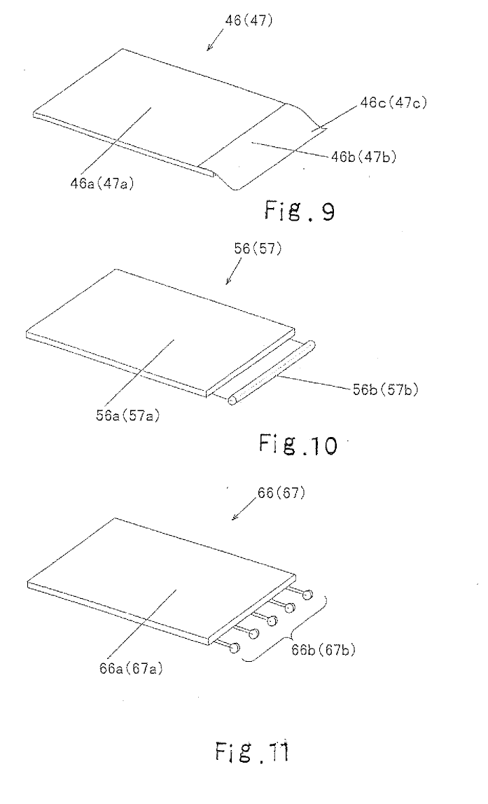

A second guide plate 46 according to a second modification in the first embodiment shown in FIG. 9 includes a main body portion having a substrate-placing surface 46a, and a guide plate 46b, serving as the leading portion, formed at the end portion (opposite end portion) of the main body portion opposite to a third guide plate 47 for leading the substrate 4 from a substrate-placing surface 47a of the third guide plate 47 to the substrate-placing surface 46a of the second guide plate 46. The guide plate 46b is provided at the opposite end portion of the substrate-placing surface 46a at the main body portion, and has a convex curved face that is gently inclined downwardly from the substrate placing surface 46a and a concave curved surface integral with the convex curved surface. The concave curved surface is defined as a concave particle receiving portion 46c for receiving a particle.

Similarly, the third guide plate 47 according to the second modification includes a main body portion having the substrate-placing surface 47a, and a guide plate 47b, serving as the leading portion, formed at the end portion (opposite end portion) of the main body portion opposite to the first guide plate 5 for leading the substrate 4 from the substrate-placing surface 5a of the first guide plate 5 to the substrate-placing surface 47a of the third guide plate 47. The guide plate 47b is provided at the opposite end portion of the substrate-placing surface 47a at the main body portion, and has a convex curved face that is gently inclined downwardly from the substrate-placing surface 47a and a concave curved surface integral with the convex curved surface. The concave curved surface is defined as a concave particle receiving portion 47c for receiving a particle.

The other configurations of the substrate transfer apparatus in the second modification are substantially the same as those of the substrate transfer apparatus D in the first embodiment.

### [Third Modification]

A second guide plate 56 according to a third modification in the first embodiment shown in FIG. 10 includes a main body portion having a substrate-placing surface 56a, and a transfer auxiliary roller 56b, serving as the leading portion, formed at the end portion (opposite end portion) of the main body portion opposite to a third guide plate 57 for leading the substrate 4 from a substrate-placing surface 57a of the third guide plate 57 to the substrate-placing surface 56a of the second guide plate 56.

The transfer auxiliary roller 56b at the second guide plate 56 is composed of a single long and slender roller as shown in FIG. 10. The transfer auxiliary roller 56b is brought into contact with the curved portion of the substrate 4 that is curved downwardly during the transfer in order to direct the curved portion upwardly, and guides the substrate 4 from the substrate-placing surface 57a of the third guide plate 57 to the substrate-placing surface 56a of the second guide plate 56.

Similarly, the third guide plate 57 according to the third modification includes a main body portion having the substrate-placing surface 57a, and a transfer auxiliary roller 57b, serving as the leading portion, formed at the end portion (opposite end portion) of the main body portion opposite to the first guide plate 5 for leading the substrate 4 from the substrate-placing surface 5a of the first guide plate 5 to the substrate-placing surface 57a of the third guide plate 57.

The transfer auxiliary roller 57b at the third guide plate 57 is composed of a single long and slender roller as shown in FIG. 10. The transfer auxiliary roller 57b is brought into contact with the curved portion of the substrate 4 that is curved downwardly during the transfer in order to direct the curved portion upwardly, and guides the substrate 4 from the substrate-placing surface 5a of the first guide plate 5 to the substrate-placing surface 57a of the third guide plate 57.

The other configurations of the substrate transfer apparatus in the third modification are substantially the same as those of the substrate transfer apparatus D in the first embodiment.

### [Fourth Modification]

A second guide plate 66 according to a fourth modification in the first embodiment shown in FIG. 11 includes a main body portion having a substrate-placing surface 66a, and a transfer auxiliary roller 66b, serving as the leading portion, formed at the end portion (opposite end portion) of the main body portion opposite to a third guide plate 67 for leading the substrate 4 from a substrate-placing surface 67a of the third guide plate 67 to the substrate-placing surface 66a of the second guide plate 66.

The transfer auxiliary roller 66b at the second guide plate 66 includes five small rollers equally spaced in the direction vertical to the transfer direction as shown in FIG. 11. The transfer auxiliary roller 66b is brought into contact with the curved portion of the substrate 4 that is curved downwardly during the transfer in order to direct the curved portion upwardly, and guides the substrate 4 from the substrate-placing surface 67a of the third guide plate 67 to the substrate-placing surface 66a of the second guide plate 66.

Similarly, the third guide plate 67 according to the fourth modification includes a main body portion having the substrate-placing surface 67a, and a transfer auxiliary roller 67b, serving as the leading portion, formed at the end portion (opposite end portion) of the main body portion opposite to the first guide plate 5 for leading the substrate 4 from the substrate-placing surface 5a of the first guide plate 5 to the substrate-placing surface 67a of the third guide plate 67.

The transfer auxiliary roller 67b at the third guide plate 67 includes five small rollers equally spaced in the direction vertical to the transfer direction as shown in FIG. 11. The transfer auxiliary roller 67b is brought into contact with the curved portion of the substrate 4 that is curved downwardly during the transfer in order to direct the curved portion upwardly, and guides the substrate 4 from the substrate-placing surface 5a of the first guide plate 5 to the substrate-placing surface 67a of the third guide plate 67.

The other configurations of the substrate transfer apparatus in the fourth modification are substantially the same as those of the substrate transfer apparatus D in the first embodiment.

### Second Embodiment

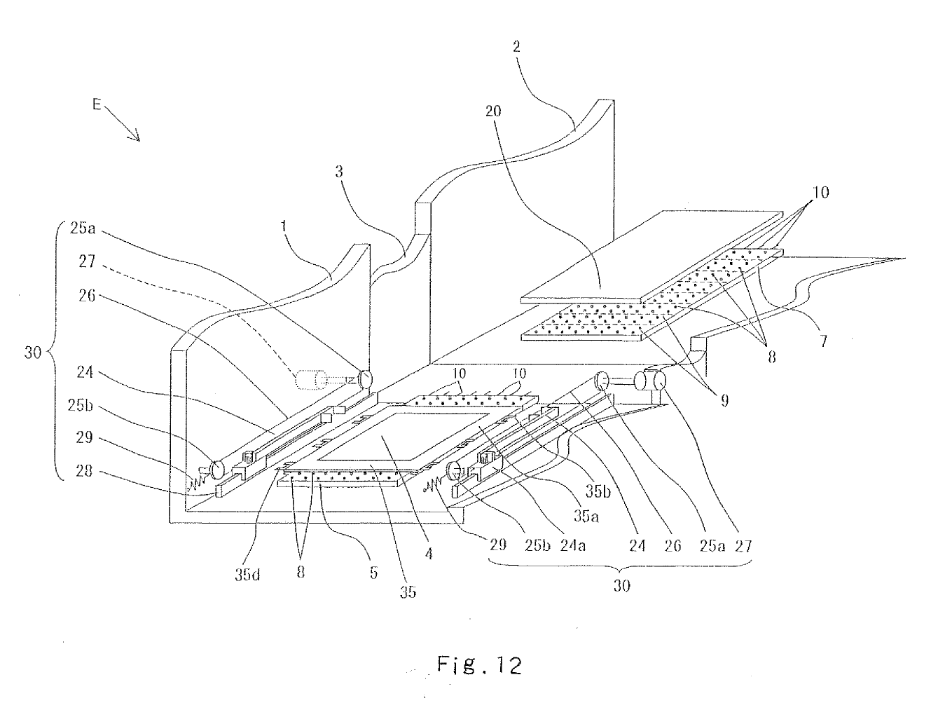

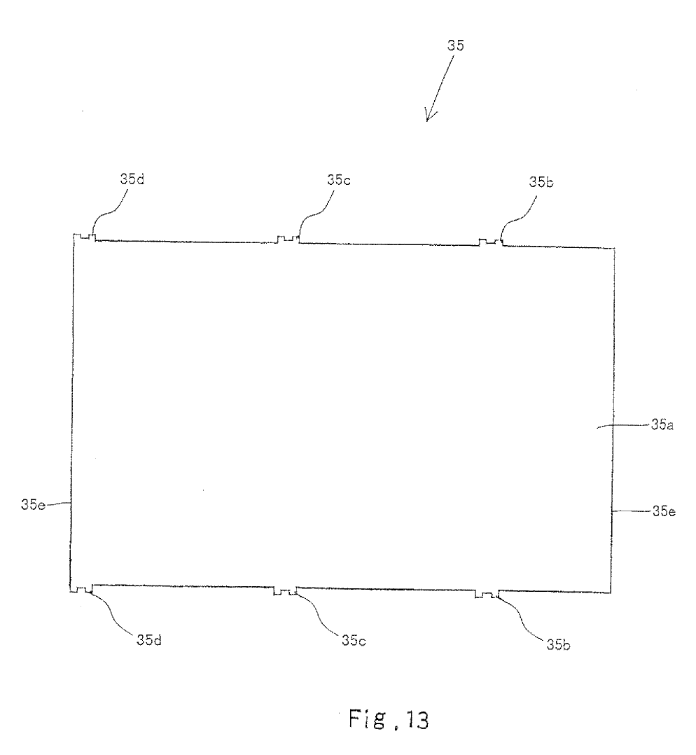

FIG. 12 is a partially cutout perspective view of a substrate transfer apparatus, which is incorporated in a plasma processing apparatus, according to a second embodiment of the present invention. FIG. 13 is a plan view of a tray for mounting a substrate, which is one component in the substrate transfer apparatus according to the second embodiment.

As shown in FIG. 12, the substrate transfer apparatus E according to the second embodiment includes the LL/UL chamber 1 and the process chamber 2 that are identical with those in the substrate transfer apparatus D in the first embodiment.

Different from the substrate transfer apparatus D in the first embodiment, the substrate transfer apparatus E employs a tray 35 for mounting the substrate 4 as shown in FIG. 13. The tray 35 is made of stainless steel, and a mirror finish is provided on the back surface thereof in order to realize a smooth transfer.

The tray 35 has a rectangular main body 35a having both side edges parallel to the transfer direction, and six projecting portions 35b, 35b, 35c, 35c, 35d, and 35d, which are formed to partially project outwardly from both side edges of the main body 35a and are brought into contact with and engaged with the transfer arm 24 or disengaged therefrom when the tray 35 is transferred by the transfer arm 24. The tray 35 is configured such that, when it is mounted to the first to third guide plates 5, 6, and 7 in the LL/UL chamber 1 and the process chamber 2, only the projecting portions 35b, . . . 35d of the main body 35a and the projecting portions 35b, . . . 35d protrude from the side edge of the guide plate.

Taper portions 35e and 35e, which are gradually reduced from the main body 35a toward the transfer direction, are respectively formed at both ends of the main body 35a.

The substrate transfer apparatus E is provided with the transfer arm 24 identical with that of the substrate transfer apparatus D. The transfer arm 24 includes the base portion 24a, the guide portion 24b, and the arm portion 24c like the transfer arm 24 of the substrate transfer apparatus D in the first embodiment.

The arm portion 24c is provided with first and second inward projecting ends 24d and 24e at its free end. The inward projecting ends 24d and 24e are brought into contact with and engaged with the respective projecting portions 35b, . . . 35d of the tray 35 or disengaged therefrom.

More specifically described, due to the reciprocating movement of the guide portion 24b, the arm 24c is apart from the rail 28 or close to the rail 28 with the parallel relationship between the arm portion 24c and the rail 28 maintained. The inward projecting ends 24d and 24e at the arm portion 24c is brought into contact with one of the projecting portions 35b, . . . 35d at the tray 35 so as to be engaged therewith from the outer side (the side more apart from the side edge of the main body 35a of the tray 35) toward the inner side (the side closer to the side edge of the main body 35a of the tray 35), or disengaged from one of the projecting portions 35b, . . . 35d at the tray 35 from the inner side toward the outer side.

The other configurations of the substrate transfer apparatus E according to the second embodiment are substantially the same as those of the substrate transfer apparatus D according to the first embodiment.

According to the substrate transfer apparatus E according to the second embodiment, the taper portions 35e and 35e of the tray 35 is brought into contact with the portion of the substrate 4 that is curved downwardly during the transfer, and smoothly guides the substrate 4 to the substrate-placing surface (7a or 6a) of the guide plate to which the substrate 4 is to be transferred (the third guide plate 7 or the second guide plate 6). Accordingly, the possibility of the trouble related to the transfer as in the conventional case can be prevented.

1. A substrate transfer apparatus comprising:
a plurality of floating-transfer guide plates adjacent to each other with a space therebetween, each of the guide plates having a substrate-placing surface on which a substrate is to be placed, and a plurality of floating-gas ejecting holes for floating the substrate with use of a gas;
a gas supplying source for supplying the floating gas to the respective guide plates; and
an arm for transferring the floated substrate from the guide plate, from which the substrate is to be transferred, to the adjacent guide plate to which the substrate is to be transferred, wherein
the substrate-placing surface of the guide plate to which the substrate is to be transferred is situated lower than the substrate-placing surface of the guide plate from which the substrate is to be transferred.

2. The substrate transfer apparatus according to claim 1, wherein
the guide plate, to which the substrate is to be transferred, opposite to the guide plate, from which the substrate is to be transferred, has an end portion provided with a leading portion for leading the substrate to be transferred from the substrate-placing surface of the guide plate from which the substrate is to be transferred to the substrate-placing surface of the guide plate to which the substrate is to be transferred.

3. The substrate transfer apparatus according to claim 2, wherein
the leading portion has a surface inclined downwardly from the substrate-placing surface of the guide plate, from which the substrate is to be transferred, to the end portion of the guide plate.

4. The substrate transfer apparatus according to claim 3, wherein
the guide plate provided with the leading portion is further provided, at its end portion, with a particle receiving portion having a concave shape for receiving a particle.

5. The substrate transfer apparatus according to claim 2, wherein
the leading portion is composed of a transfer auxiliary roller.

6. The substrate transfer apparatus according to claim 5, wherein
the transfer auxiliary rollers are provided in plural member so as to be spaced from each other in a direction vertical to a transfer direction of the substrate.

7. The substrate transfer apparatus according to claim 1, wherein
at least one of the guide plate from which the substrate is to be transferred and the guide plate to which the substrate is to be transferred moves up and down by means of an elevation mechanism in order to change a height of the substrate-placing surface of the guide plate.

8. The substrate transfer apparatus according to claim 1, further comprising:
a tray on which the substrate is mounted, the tray being floated by the floating gas, wherein
the tray has a taper portion whose thickness gradually decreases in the transfer direction, the taper portion being placed at an end portion of the tray opposite to the guide plate to which the substrate is to be transferred.
